(19) United States
(12) Patent Application Publication
(10) Pub. No.: US 2011/0171800 A1
(43) Pub. Date: Jul. 14, 2011

(54) METHOD OF FORMING SEMICONDUCTOR DEVICES WITH BURIED GATE ELECTRODES AND DEVICES FORMED BY THE SAME

(75) Inventors: Bongsoo Kim, Seongnam-si (KR); Chul Lee, Seoul (KR); Deoksung Hwang, Yongin-si (KR); Sang-Bin Ahn, Incheon (KR)

(73) Assignee: Samsung Electronics Co., Ltd.

(21) Appl. No.: 12/944,870

(22) Filed: Nov. 12, 2010

(30) Foreign Application Priority Data
Jan. 11, 2010 (KR) 10-2010-0002347

(51) Int. Cl. H01L 21/336

(52) U.S. Cl. 438/272; 257/E21.429

(57) ABSTRACT

A polycrystalline semiconductor layer is formed on a cell active region and a peripheral active region of a substrate. A buried gate electrode is formed in the substrate in the cell active region at a level below the polycrystalline semiconductor layer after forming the polycrystalline semiconductor layer. A gate electrode is formed on the substrate in the peripheral active region from the polysilicon semiconductor layer after forming the buried gate electrode.

### CROSS-REFERENCE TO RELATED APPLICATIONS

This U.S. non-provisional patent application claims priority under 35 U.S.C. §119 of Korean Patent Application No. 10-2010-0002347, filed on Jan. 11, 2010, the entire contents of which are hereby incorporated by reference.

### BACKGROUND

The present inventive subject matter relates to methods of forming semiconductor devices and semiconductor devices formed by the same, and more particularly, to methods of forming semiconductor devices with buried gate electrodes and devices formed using these methods.

According to a trend toward high integration in the semiconductor devices, there have been ongoing efforts to reduce dimensions of components and spaces between components in semiconductor devices. However, there are technical limitations on the reduction of dimensions, and reducing dimensions may also degrade device characteristics. For example, narrowing distances between the source/drain regions of transistors may lead to undesirable short channel effects.

### SUMMARY

Some embodiments of the inventive subject matter provide methods of fabricating semiconductor devices. The methods include forming a polycrystalline semiconductor layer on a cell active region and a peripheral active region of a substrate and removing portions of the polycrystalline semiconductor layer and the substrate in the cell active region to form a gate trench in the cell active region. A gate electrode is formed in the gate trench. Portions of the polycrystalline semiconductor layer are removed to form a peripheral gate electrode on the substrate in the peripheral active region.

An insulating pattern may be formed on the gate electrode in the gate trench. Forming an insulating pattern on the gate electrode in the gate trench may include depositing an insulating material layer on the substrate in the gate trench and on a portion of the cell active region adjacent the gate trench and etching the insulating material layer to form the insulating pattern. A top surface of the insulating pattern may be lower than a top surface of the polycrystalline semiconductor layer.

The methods may further include forming a capping pattern on the insulating pattern between opposing sidewalls of the polycrystalline semiconductor layer. The capping pattern may include a polycrystalline semiconductor having a crystallinity that is different from a crystallinity of the polycrystalline semiconductor layer.

Removing portions of the polycrystalline semiconductor layer and the substrate in the cell active region to form a gate trench in the cell active region may be preceded by forming a mask pattern and an insulating layer on the polycrystalline semiconductor layer. The insulating layer may include a medium temperature oxide (MTO). A capping pattern may be formed on the insulating pattern between portions of the polycrystalline semiconductor layer using the insulating layer as etch stop layer.

Forming a gate electrode in the gate trench may include forming a conductive material layer on the substrate to fill the gate trench and etching the conductive material layer to form the gate electrode such that a top surface of the gate electrode is lower than a top surface of the cell active region.

Further embodiments provide methods including forming a polycrystalline semiconductor layer on a cell active region and a peripheral active region of a substrate, forming a buried gate electrode in the substrate in the cell active region at a level below the polycrystalline semiconductor layer after forming the polycrystalline semiconductor layer and forming a gate electrode on the substrate in the peripheral active region from the polycrystalline semiconductor layer after forming the buried gate electrode. Forming a buried gate electrode in the substrate in the cell active region at a level below the polycrystalline semiconductor layer after forming the polycrystalline semiconductor layer may include forming the buried gate electrode in a trench extending through the polycrystalline semiconductor layer and into the substrate. The methods may further include forming a polycrystalline semiconductor capping pattern in the trench on the gate electrode between opposing sidewalls of the polycrystalline semiconductor layer. The polycrystalline semiconductor capping pattern may have a different crystallinity than the polycrystalline semiconductor layer.

Further embodiments provide a semiconductor device including a substrate having a cell active region and a peripheral active region. A polycrystalline semiconductor pattern is disposed on the substrate in the cell active region. A gate electrode may be disposed in a gate trench in the polycrystalline semiconductor pattern and the substrate in the cell active region, and an insulating pattern may be disposed on the gate electrode in the gate trench. A capping pattern may be disposed on the insulating pattern between sidewalls of the polycrystalline semiconductor layer. A polycrystalline semiconductor peripheral gate electrode may be disposed on the substrate in the peripheral active region. The capping pattern may include a polycrystalline semiconductor having a crystallinity different from a crystallinity of the polycrystalline semiconductor pattern and a crystallinity of the peripheral gate electrode. The polycrystalline semiconductor peripheral gate electrode may have the same crystallinity as the polycrystalline semiconductor pattern. A bottom surface of the polycrystalline semiconductor pattern may be at the same level as a bottom surface of the polycrystalline semiconductor peripheral gate electrode.

### BRIEF DESCRIPTION OF THE DRAWINGS

The accompanying drawings are included to provide a further understanding of the inventive subject matter, and are incorporated in and constitute a part of this specification. The drawings illustrate exemplary embodiments of the inventive subject matter and, together with the description, serve to explain principles of the inventive subject matter. In the figures:

FIG. 1 is a plan view illustrating a semiconductor device according to some embodiments of the inventive subject matter; and

FIGS. 2 through 10 are cross sectional views illustrating operations for forming a semiconductor device according to some embodiments of the inventive subject matter.

### DETAILED DESCRIPTION

Exemplary embodiments of the inventive subject matter will be described below in more detail with reference to the accompanying drawings. The embodiments of the inventive subject matter may, however, be embodied in different forms and should not be construed as limited to the embodiments set forth herein. Rather, these embodiments are provided so that this disclosure will be thorough and complete, and will fully convey the scope of the inventive subject matter to those skilled in the art. In this specification, the meaning of ‘comprises’ and/or ‘comprising’ does not exclude other components besides a mentioned component it will also be understood that when another component is referred to as being ‘on’ one component, and it can be directly on the one component, or an intervening third component may also be present. Though terms like a first, a second, and a third are used to describe various regions and layers in various embodiments of the inventive subject matter, the regions and the layers are not limited to these terms. These terms are only used to distinguish one component from another component. Also, in the figures, the dimensions of layers and regions are exaggerated for clarity of illustration.

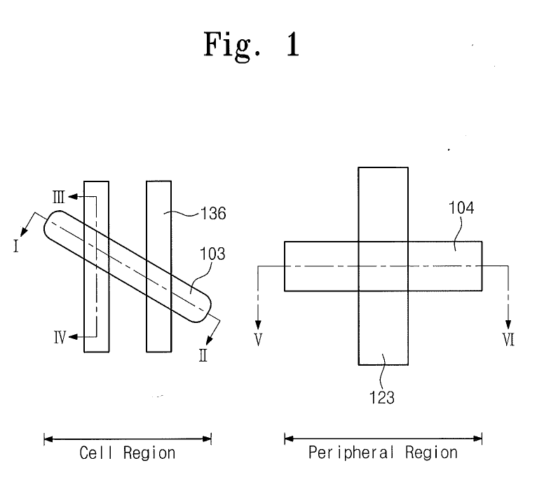

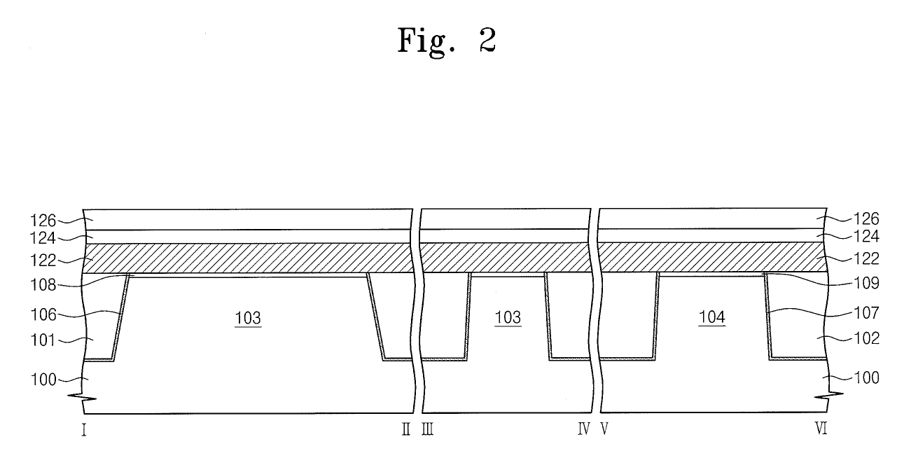

FIG. 1 is a plan view illustrating a semiconductor device according to some embodiments of the inventive subject matter. FIGS. 2 through 10 are cross sectional views taken along lines I-II, III-IV and V-VI of FIG. 1, and illustrate operations for forming a semiconductor device according to some embodiments of the inventive subject matter.

Referring to FIGS. 1 and 2, a cell active region 103 and a peripheral active region 104 may be defined on a substrate 100 having a cell region and a peripheral region. The cell active region 103 and the peripheral active region 104 may be defined by forming a cell trench and a peripheral trench on the substrate 100, and injecting dopants in the substrate to form well regions. The cell trench and the peripheral trench may be simultaneously or separately formed. A cell trench liner 106 and a peripheral trench liner 107 may be formed on sidewalls and bottoms of the cell trench and the peripheral trench. The cell trench liner 106 and the peripheral trench liner 107 may include a semiconductor nitride.

A cell device isolation layer 101 and a peripheral device isolation layer 102 are formed in the cell trench and the peripheral trench, respectively. The cell device isolation layer 101 and the peripheral device isolation layer 102 may be formed by filling the cell trench and the peripheral trench with an insulating layer and planarizing the insulating layer. The cell trench liner 106 and the peripheral trench liner 107 on the substrate 100 out of the cell trench and the peripheral trench may be removed by the planarizing process, thereby exposing top surfaces of the cell active region 103 and the peripheral active region 104.

A cell insulating layer 108 and a peripheral insulating layer 109 may be formed on the cell active region 103 and the peripheral active region 104, respectively. The peripheral insulating layer 109 may correspond to a gate insulating layer of a peripheral transistor. The cell insulating layer 108 and the peripheral insulating layer 109 may be formed by thermally oxidizing portions of the cell active region 103 and the peripheral active region 104. The cell insulating layer 108 and the peripheral insulating layer may also be formed by a deposition process, such as by chemical vapor deposition (CVD) and/or atomic layer deposition (ALD).

A polycrystalline semiconductor layer 122 is formed on the cell active region 103 and the peripheral active region 104. The polycrystalline semiconductor layer 122 may be used to form a gate electrode on the peripheral active region 104. The polycrystalline semiconductor layer 122 may have sufficient thickness to be operable as the gate electrode and to consider a process margin of following processes. For example, the polycrystalline semiconductor layer 122 may be formed to a thickness of several hundred Angstroms. The polycrystalline semiconductor layer 122 may be doped with dopants. The polycrystalline semiconductor layer may be doped by, for example, implanting dopants into the polycrystalline semiconductor layer 122 and performing rapid thermal annealing (RTA).

An insulating layer 124 may be formed on the polycrystalline semiconductor layer 122. The insulating layer 124 may be used as an etch stop layer during a subsequent etching of a capping layer to form a capping pattern described below. The insulating layer 124 may include, for example, a medium temperature oxide (MTO) layer. The insulating layer 124 may also be formed of an insulating material having an etching selectivity with respect to the capping layer.

A mask layer 126 may be formed on the insulating layer 124. The mask layer 126 may include, for example a semiconductor nitride.

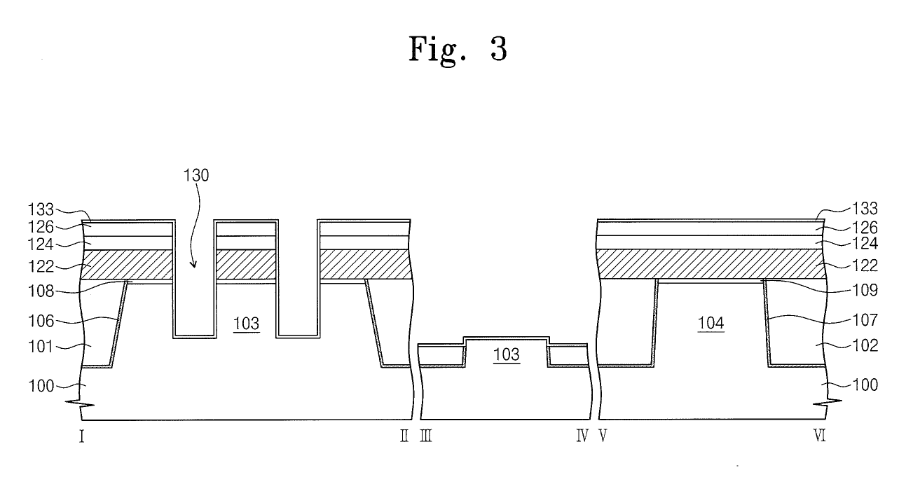

Referring to FIGS. 1 and 3, a gate trench 130 is formed in the cell active region 103. The gate trench 130 may be formed, for example, by patterning the mask layer 126 and etching the substrate 100 using the patterned mask layer 126 as an etch mask. A sidewall of the cell active region 103 may be exposed in forming the gate trench 130. The height of the mask layer 126 may be lowered during the etching process that forms the gate trench 130.

A cell gate insulating layer 133 may be formed in the gate trench 130. The cell gate insulating layer 133 may include, for example, an oxide, nitride; oxynitride and/or other insulating materials. The cell gate insulating layer 133 may be formed, for example, by thermal oxidizing the inner wall of the exposed gate trench 130 or formed by depositing an insulating layer in the cell gate trench 130.

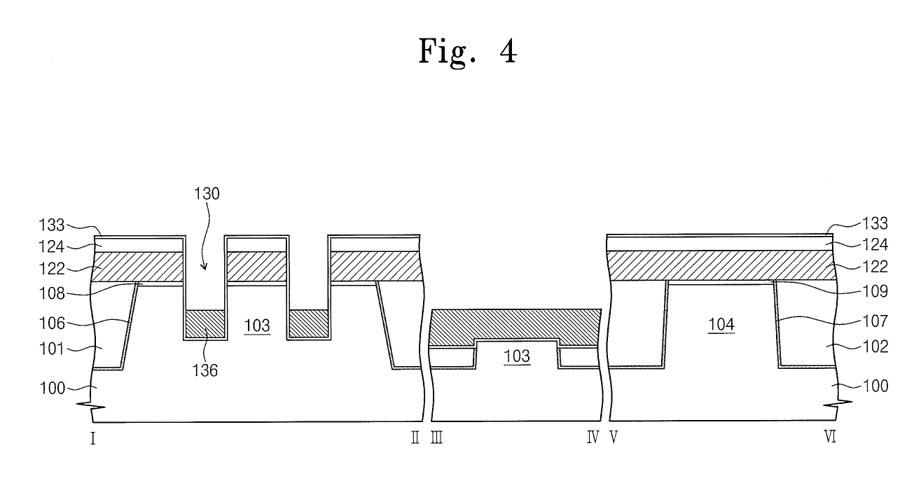

Referring to FIG. 4, a buried gate electrode 136 may be formed on a bottom of the gate trench 130. The buried gate electrode 136 may be formed by filling the gate trench 130 with conductive material and etching back the conductive material. The etching back may be substituted to another etching process.

The top surface of the buried gate electrode 136 may be lower than the top surface of the cell active region 103. The buried gate electrode 136 may include, for example, titanium nitride (TiN), tantalum nitride (TaN) and tungsten nitride (WN), titanium, tantalum, tungsten and aluminum, doped semiconductor and/or other conductive materials.

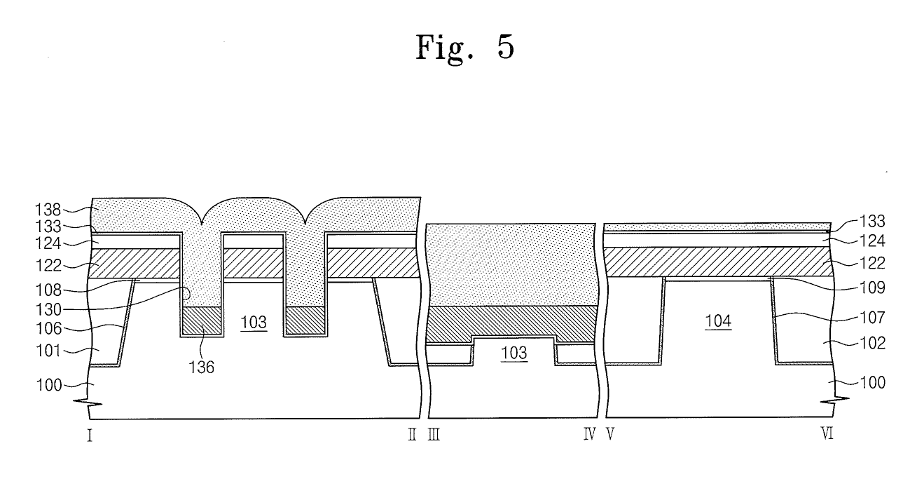

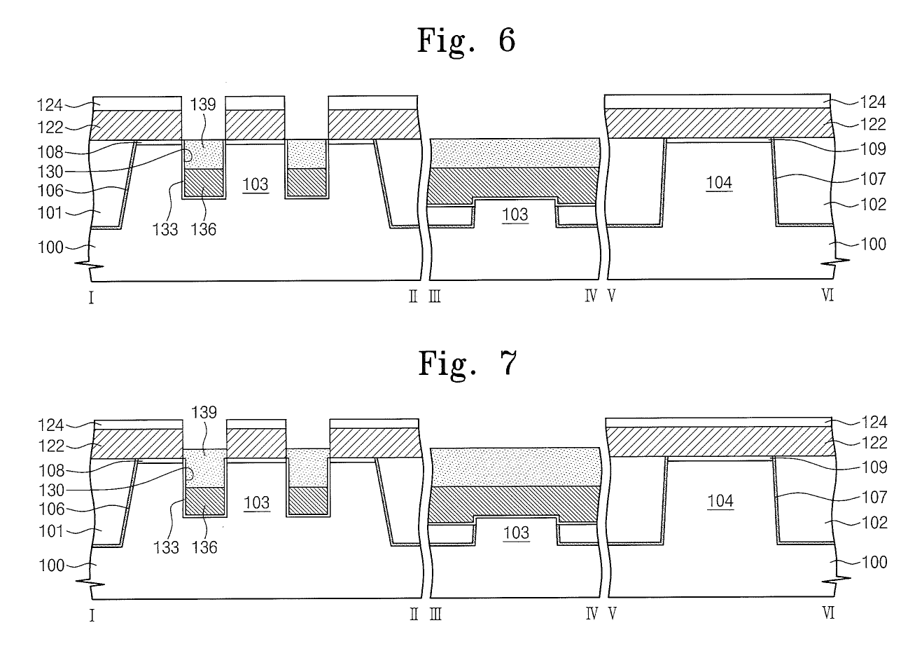

Referring to FIGS. 5 and 6, a buried insulating layer 139 may be formed to fill the gate trench 130 where the buried gate electrode 136 is formed. The buried insulating layer 139 may be formed, for example, by depositing an insulating layer 138 in the gate trench 130 and etching the deposited insulating layer 138 to form the buried insulating layer 139. The buried insulating layer 139 may be formed to a uniform thickness under the influence of the polycrystalline semiconductor layer 122 having sufficient thickness.

Several polysilicon layers may be formed to form the peripheral gate electrode. In such a case, a polysilicon layer, formed just prior to forming a buried insulating layer, may be formed relatively thinner than described above. Therefore, an etching target may be difficult to be accurately controlled when the etching of the buried insulating layer in the gate trenches and between the polysilicon layers formed relatively thinly. Therefore, the buried insulating layer may not be etched uniformly.

In some embodiments of the inventive subject matter, when etching the buried insulating layer 139, the etching target may be accurately controlled under the influence of the polycrystalline semiconductor layer 122 because the polycrystalline semiconductor layer 122 is formed to a sufficient thickness before forming the gate trench 130. Therefore, the etching process of the buried insulating layer 139 can be improved in accuracy. Accordingly, non-uniformity in a polycrystalline semiconductor layer formed by repeatedly forming layers may be reduced by, for example, reducing crystal deviation and interposition of oxide layers between the repeatedly formed polycrystalline semiconductor layers. As a result, characteristics of the peripheral gate electrode which is formed by etching the polycrystalline semiconductor layer 122 can be improved.

A portion of the cell gate insulating layer 133 may be etched to expose a portion of the polycrystalline semiconductor layer 122. The buried insulating layer 139 and the cell gate insulating layer 133 may be etched using, for example, a wet etching process.

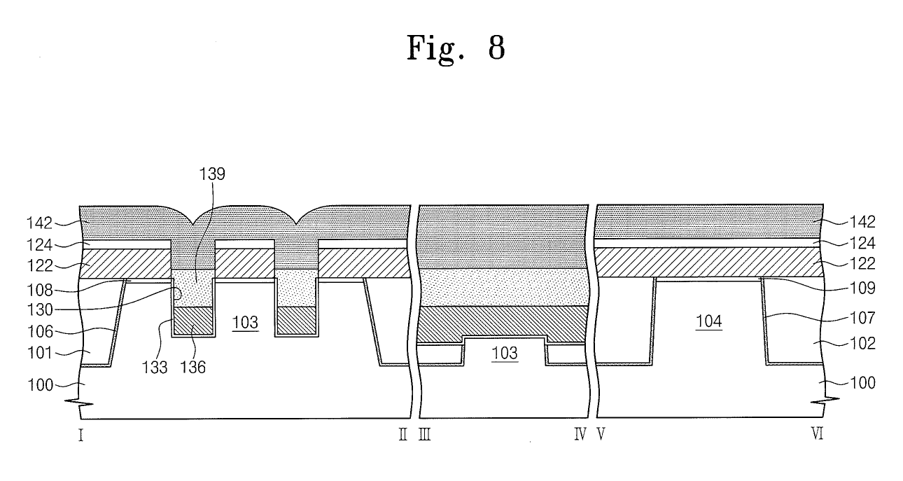

Referring to FIG. 7, the filling of the buried insulating layer 139 in the gate trench 130 and the etching of the buried insulating layer 139 may be alternately performed several times, thereby allowing adjustment of the height of the buried insulating layer 139. If a wet etching process is used, the top surface of the etched cell gate insulating layer 133 may be lower than the top surface of the buried insulating layer 139. The top surface of the etched cell gate insulating layer 133 may be covered with the buried insulating layer 139. In some embodiments, the buried insulating layer 139 may be formed by forming the layer at a time and etching this layer. In this case, the etched cell gate insulating layer 133 and the etched buried insulating layer may have coplanar top surfaces.

Referring to FIG. 8, a capping layer 142 may be formed to fill the gate trench 130. The capping layer 142 may fill the gate trench 130 and cover the insulating layer 124. The capping layer 142 may include, for example, a polycrystalline semiconductor.

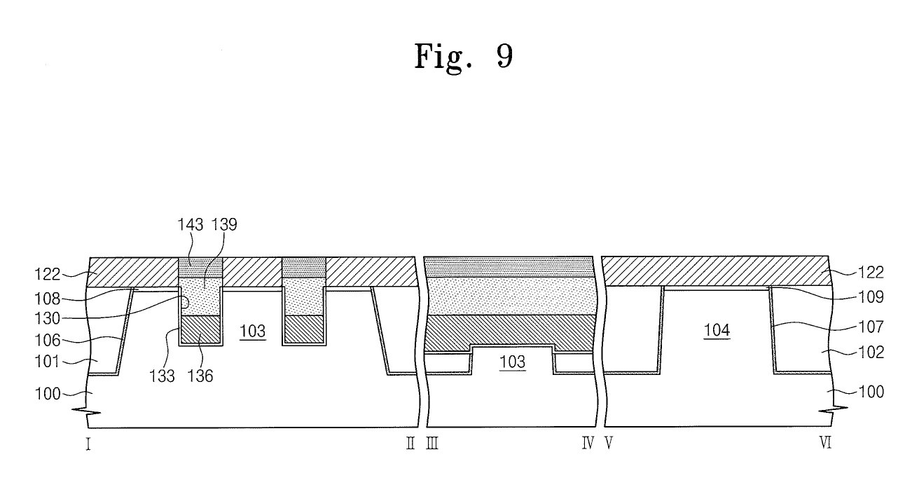

Referring to FIG. 9, the capping layer 142 is etched to form a capping pattern 143. In the etching process, the insulating layer 124 may be used as an etch stop layer. The top surface of the capping pattern 143 may be coplanar with the top surface of the polycrystalline semiconductor layer 122. The capping pattern 143 may be selectively formed on the cell region. For example, the capping layer 142 on the peripheral region may be selectively etched during the etching of the capping layer 142.

The polycrystalline semiconductor layer 122 may be crystallized by heating during succeeding processes of forming layers. However, because the capping layer 142 may be formed after these processes, it thereby may have a degree of crystallinity lower than the polycrystalline semiconductor layer 122. Thus, the polycrystalline semiconductor layer 122 and the capping layer 142 may have different degrees of crystallization. In addition, an oxide layer may be formed on a sidewall and top surface of the polycrystalline semiconductor layer 122.

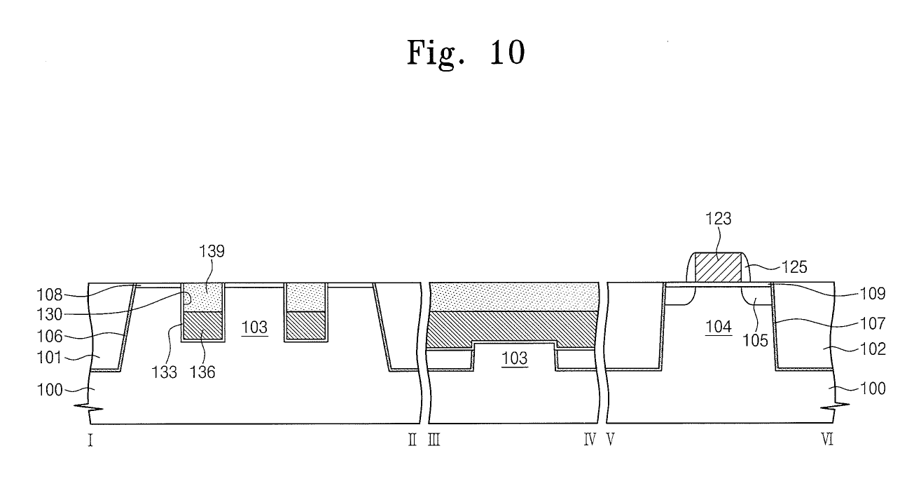

Referring to FIG. 10, the polycrystalline semiconductor layer 122 is etched to form a peripheral gate electrode 123 on the peripheral region. The polycrystalline semiconductor layer 122 and the capping pattern 143 on the cell active region 103 may be removed during the etching process. In some embodiments, the polycrystalline semiconductor layer 122 and the capping pattern 143 on the cell active region 103 may not be removed, and may remain on the cell region as shown in FIG. 9.

After formation of the peripheral gate electrode 123, peripheral source/drain regions 105 may be formed in the peripheral active region 104 on respective sides of the peripheral gate electrode 123. The peripheral source/drain region 105 may be formed, for example, by an ion implantation process using the peripheral gate electrode 123 as an ion implantation mask. A spacer 125 may be formed on a sidewall of the peripheral gate electrode 123.

According to the above-described embodiments of the inventive subject matter, the peripheral gate electrode 123 may be formed from a single layer of polycrystalline semiconductor layer 122. In contrast, some conventional techniques for forming a buried gate electrode involve forming a gate electrode from several polycrystalline silicon layers. For example, in some conventional processes, polysilicon layers for a gate electrode in a peripheral region may be formed before forming the gate trench and after forming the buried gate electrode and the buried insulating layer on the buried gate electrode. The polysilicon layer formed after forming the buried gate electrode may not be crystallized while the polysilicon layer formed prior to forming the gate trench may be crystallized by heat in succeeding processes. Therefore, the polysilicon layer may be non-uniform and an insulating layer may be formed between the polysilicon layers by oxidation. If dopants are injected in the polysilicon layer, the dopants may leak through an interface of the crystallized polysilicon layers, which may alter characteristics of the semiconductor device.

In contrast, in some embodiments of the inventive subject matter, a peripheral gate electrode with relatively uniform crystallinity may be provided because the polycrystalline semiconductor layer from which the electrode is formed is deposited prior to forming the gate trench. Therefore, a peripheral gate electrode so formed may exhibit superior characteristics.

Referring to FIGS. 1 and 10, a semiconductor device according to some embodiments of the inventive subject matter will be described. A substrate 100 having a cell region and a peripheral region is provided. A cell active region 103 and a peripheral active region 104 are defined on the cell region and the peripheral region, respectively. The cell active region 103 and the peripheral active region 104 may be defined by a cell device isolation layer 102 and a peripheral device isolation layer 103, respectively. A cell trench liner 106 may be disposed between the substrate 100 and the cell device isolation layer 101, and a peripheral trench liner 107 may be disposed between the substrate 100 and the peripheral device isolation layer 102. A cell insulating layer 108 and a peripheral insulating layer 109 may be respectively disposed on the substrate 100 of the cell active region 103 and the peripheral active region 104. The peripheral insulating layer 109 may be a gate insulating layer of the peripheral transistor.

A gate trench 130 may be defined on the cell active region 103. A portion of the substrate 100 of the cell active region 103 may be recessed to define the gate trench 130. A cell gate insulating layer 133 may be disposed on a sidewall and a bottom of the gate trench 130. Impurity regions may be disposed in the cell active region 103 at respective sides of the gate trench 130. The impurity regions may be source/drain regions of a cell transistor.

A buried gate electrode 136 is disposed on the cell gate insulating layer 133 in the gate trench 130. The buried gate electrode 136 may have a top surface below the top surface of the cell active region 103. The buried gate electrode 136 may be filled in a lower portion of the gate trench 130.

A buried insulating layer 139 may be disposed on the buried gate electrode 139. The buried insulating layer 139 may fill an upper portion of the gate trench 130.

In some embodiments, a polycrystalline semiconductor layer may be left on the buried insulating layer 139. For example, the cell active region of the semiconductor device may include a polycrystalline semiconductor layer 122 and a capping pattern 143 on the substrate including a buried insulating layer 139 as shown in FIG. 9. The capping pattern 143 may include a polycrystalline semiconductor with a different crystallization than the polycrystalline semiconductor layer 122. For example, the semiconductor in the polycrystalline semiconductor layer 122 may be more crystallized than the semiconductor in the capping pattern 143. An oxide layer may be disposed between the polycrystalline semiconductor layer 122 and the capping pattern 143.

A peripheral gate electrode 123 may be disposed on the peripheral active region 104. The peripheral gate electrode 123 may be disposed at a level higher than the buried gate electrode 136. For example, if the top surfaces of the cell active region 103 and the peripheral active region 104 are substantially on the same level, the peripheral gate electrode 123 may be disposed on a level higher than the top surfaces of the cell active region 103 and the peripheral active region 104, and the buried gate electrode 136 may be disposed on a level lower the top surfaces of the cell active region 103 and the peripheral active region 104. Peripheral source/drain regions 105 may be disposed in the peripheral active region 104 at respective sides of the peripheral gate electrode 123. The peripheral source/drain region 105 may be disposed in the peripheral active region 104 at a level substantially the same as the upper surface of the cell active region 103.

The peripheral gate electrode 123 may be formed from a single layer of polycrystalline semiconductor, and may exhibit a substantially uniform crystallization. In some embodiments, if the polycrystalline semiconductor layer 122 is left on the cell region as shown in FIG. 9, the peripheral gate electrode 123 may be the same material and crystallization as the polycrystalline semiconductor layer 122. In addition, the top surface and the bottom surface of the peripheral gate electrode 123 may have the same height as the top surface and the bottom surface, respectively, of the polycrystalline semiconductor layer 122.

According to some embodiments of the inventive subject matter, gate electrodes with improved uniformity and minimized disturbance between adjacent cells can be formed. Thereby, the reliability of semiconductor devices so formed may be improved.

The above-disclosed subject matter is to be considered illustrative and not restrictive, and the appended claims are intended to cover all such modifications, enhancements, and other embodiments, which fall within the true spirit and scope of the inventive subject matter. Thus, to the maximum extent allowed by law, the scope of the inventive subject matter is to be determined by the broadest permissible interpretation of the following claims and their equivalents, and shall not be restricted or limited by the foregoing detailed description.

1. A method comprising:
forming a polycrystalline semiconductor layer on a cell active region and a peripheral active region of a substrate;
removing portions of the polycrystalline semiconductor layer and the substrate in the cell active region to form a gate trench in the cell active region;
forming a gate electrode in the gate trench; and
removing portions of the polycrystalline semiconductor layer to form a peripheral gate electrode on the substrate in the peripheral active region.

2. The method of claim 1, further comprising doping the polycrystalline semiconductor layer.

3. The method of claim 1, wherein the peripheral gate electrode comprises a single polycrystalline semiconductor layer.

4. The method of claim 1, wherein the polycrystalline semiconductor layer is thicker than the peripheral gate electrode.

5. The method of claim 1, further comprising forming an insulating pattern on the gate electrode in the gate trench.

6. The method of claim 5, further comprising forming a capping pattern on the insulating pattern between opposing sidewalls of the polycrystalline semiconductor layer.

7. The method of claim 6, wherein the capping pattern comprises a polycrystalline semiconductor having a crystallinity different from a crystallinity of the polycrystalline semiconductor layer.

8. The method of claim 1, wherein removing portions of the polycrystalline semiconductor layer and the substrate in the cell active region to form a gate trench in the cell active region is preceded by forming a mask pattern and an insulating layer on the polycrystalline semiconductor layer.

9. The method of claim 8, wherein the insulating layer comprises a medium temperature oxide (MTO).

10. The method of claim 8, further comprising further comprising forming a capping pattern on the insulating pattern between portions of the polycrystalline semiconductor layer using the insulating layer as etch stop layer.

11. The method of claim 1, wherein forming a gate electrode on a bottom surface in the gate trench comprises:
forming a conductive material layer on the substrate to fill the gate trench; and
etching the conductive material layer to form the gate electrode such that a top surface of the gate electrode is lower than a top surface of the cell active region.

12. A method comprising:
forming a polycrystalline semiconductor layer on a cell active region and a peripheral active region of a substrate;
forming a buried gate electrode in the substrate in the cell active region at a level below the polycrystalline semiconductor layer after forming the polycrystalline semiconductor layer; and
forming a gate electrode on the substrate in the peripheral active region from the polysilicon semiconductor layer after forming the buried gate electrode.

13. The method of claim 12, wherein forming a buried gate electrode in the substrate in the cell active region at a level below the polycrystalline semiconductor layer after forming the polycrystalline semiconductor layer comprises forming the buried gate electrode in a trench extending through the polycrystalline semiconductor layer and into the substrate.

14. The method of claim 13, further comprising forming a polycrystalline semiconductor capping pattern in the trench on the gate electrode between opposing sidewalls of the polycrystalline semiconductor layer.

15. The method of claim 14, wherein the polycrystalline semiconductor capping pattern has a different crystallinity than the polycrystalline semiconductor layer.

16.-20. (canceled)
